(19) United States
(12) Patent Application Publication
(10) Pub. No.: US 2012/0319241 A1
(43) Pub. Date: Dec. 20, 2012

(54) OFFSET REDUCING RESISTOR CIRCUIT

(75) Inventors: Yijing LIN, Beijing (CN); Damien MCCARTNEY, Raheen (IE)

(73) Assignee: ANALOG DEVICES, INC., Norwood, MA (US)

(21) Appl. No.: 13/523,469

(22) Filed: Jun. 14, 2012

Related U.S. Application Data
(60) Provisional application No. 61/498,244, filed on Jun. 17, 2011.

(51) Int. Cl. H01L 27/01

(52) U.S. Cl. 257/538; 257/E27.114

(57) ABSTRACT

The resistor segments may be placed in a spatial region of an integrated circuit. Junctions formed between the resistor segments and conductors may be placed at locations such that each junction has a paired counterpart of the same type that is spaced to form respective same junction type centroids (i.e., geometric centers). The different type centroids may be substantially coincident, meaning that the centroids substantially overlap. In this manner, junction voltages (or offset voltages) generated by one pair of junctions may cancel out the junction voltages generated by another pair of junctions in the resistor circuit.

### CROSS-REFERENCE TO RELATED APPLICATION

This application claims the benefit of priority afforded by provisional application Ser. No. 61/498,244, filed Jun. 17, 2011.

### BACKGROUND

The present invention relates to techniques for reducing voltage offsets that can arise in integrated circuits and, specifically, to those voltage offsets that can arise in semiconductor resistors within such integrated circuits.

In semiconductor resistors, a voltage offset is a voltage that is generated at the junction between a metal and a semiconductor material. Voltage offsets cause integrated circuits to behave in non-ideal manners. Although electrical engineers typically model a resistor according to the equation V=I*R , where V represents a driving voltage across the resistor, I represents a current passing through the resistor and R represents the resistance of the material that constitutes the resistor, in practice the resistor may behave as V=I*R+ΣV_{OFFi}, where V_{OFFi} represents the voltages induced by various metal-to-semiconductor junctions within the resistor. In applications requiring high precision operation, the voltage offsets cause a loss of precision.

Voltage offsets arise in other circuit systems, such as amplifiers. Various techniques to reduce voltage offsets are utilized such systems, such as chopper stabilizers and auto-zero circuits, however, such techniques are unable to combat all offset phenomena. For example, chopper stabilizers reduce offset voltages generated in amplifiers by modulating the offset voltages and suppressing them in low pass filters. Although chopper stabilizers are effective in reducing offset voltages generated in amplifiers, they are unable to reduce offset voltages generated by other circuit components. The present disclosure focuses on reducing offset voltages generated by a resistor structure that has a resistor body made of semiconductor material and terminals made of conductive material.

FIG. 1 is a cross-section of a typical poly silicon resistor 100 that generates undesired offset voltages. Metal tracks 110 (e.g., aluminum or copper) attach to contact materials 120 (e.g., TiSi₂). The contact materials 120 attach to a poly silicon film 130. According to the Seebeck effect, a voltage potential is generated when two different conductive materials contact at a junction. This potential is a function of the contacting materials and proportional to temperature (the function is approximately linear for small temperature ranges). The junction between the conductive materials is called a thermocouple. For the poly silicon resistor 100 in FIG. 1, there are two such thermocouples 140 at each junction of the poly silicon resistor 100. The thermocouples 140 are (a) between the metal tracks 110 and the contact materials 120 and (b) between the contact materials 120 and the poly-silicon film 130.

If there is a temperature difference between the metal tracks 110 of the poly silicon resistor 100, a voltage potential (or offset voltage) is observable. In other words, the resistor becomes a “thermocouple” in this condition. The typical value of the voltage potential generated in a metal-silicon junction is approximately 400 μV/° C. In such circumstances, a mere 0.01° C. temperature difference across poly silicon resistor 100 will generate a few μ_{V} potential difference between the metal tracks 110. Modern circuit applications often require offset to be reduced to 0.01 μV. The situation is more serious when circuits dissipate significant power which induces greater temperature differences across resistors. Therefore, a need exists for an offset reducing technique that accounts for temperature variances across resistors.

### BRIEF DESCRIPTION OF THE DRAWINGS

FIG. 1 illustrates a poly silicon resistor structure that generates undesired offset voltages.

FIG. 2 illustrates a resistor structure according to an embodiment of the present invention.

FIG. 3 is a circuit model of the resistor of FIG. 2.

FIG. 4 illustrates a resistor structure according to another embodiment of the present invention.

FIG. 5 is a circuit model of the resistor of FIG. 4.

FIG. 6 illustrates a resistor structure according to another embodiment of the present invention.

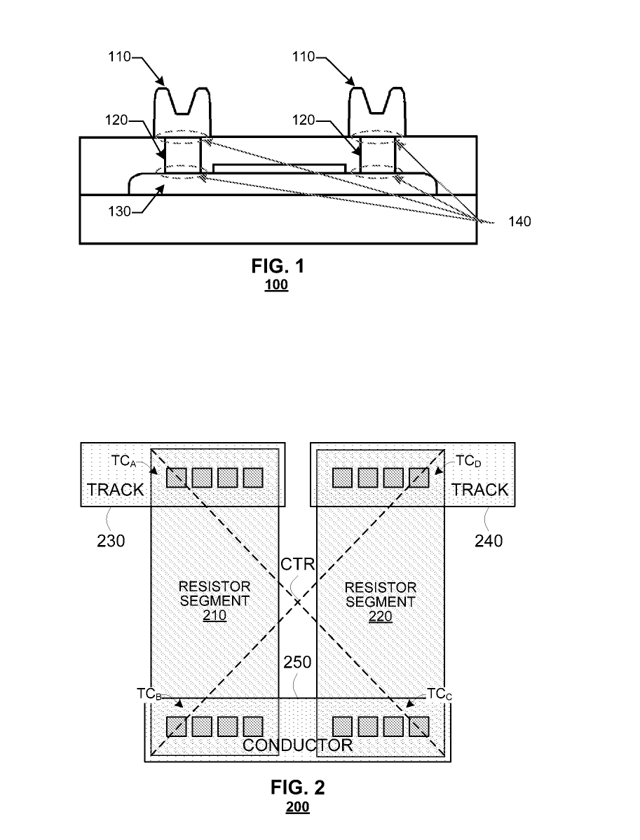

### DETAILED DESCRIPTION

Embodiments of the present invention provide an integrated circuit structure for a resistor that minimizes offset voltages that occur at material junctions in typical semiconductor resistor circuits. The invention may include at least two resistor segments that may be interconnected via metal conductors. The resistor segments may be placed in a spatial region of an integrated circuit. Junctions formed between the resistor segments and conductors may be placed at locations such that each junction has a paired counterpart of the same type (i.e., current flow direction type) that is spaced to form respective same junction type centroids (i.e., geometric centers). The different junction type centroids may be substantially coincident, meaning that the centroids substantially overlap. In this manner, junction voltages (or offset voltages) generated by one pair of junctions may cancel out the junction voltages generated by another pair of junctions in the resistor circuit.

Additionally, because the centroids of paired junctions are substantially coincident, the junction voltages are likely to vary with temperature in an equal but opposite manner. Thus, the cancellation effect should persist even when temperature varies.

The principles of the present invention may find application in any resistor structure that has a resistor body made of semiconductor material. For example, the resistor segments of the present invention may be poly silicon resistors, N-type or P-Type diffusion resistors, or N-type or P-type well resistors. The resistor segments of the embodiments are coupled with metal conductors. However, other conductive materials may be utilized instead of metal. Moreover, the resistor segments may be utilized as connection pads, for example bonding pads.

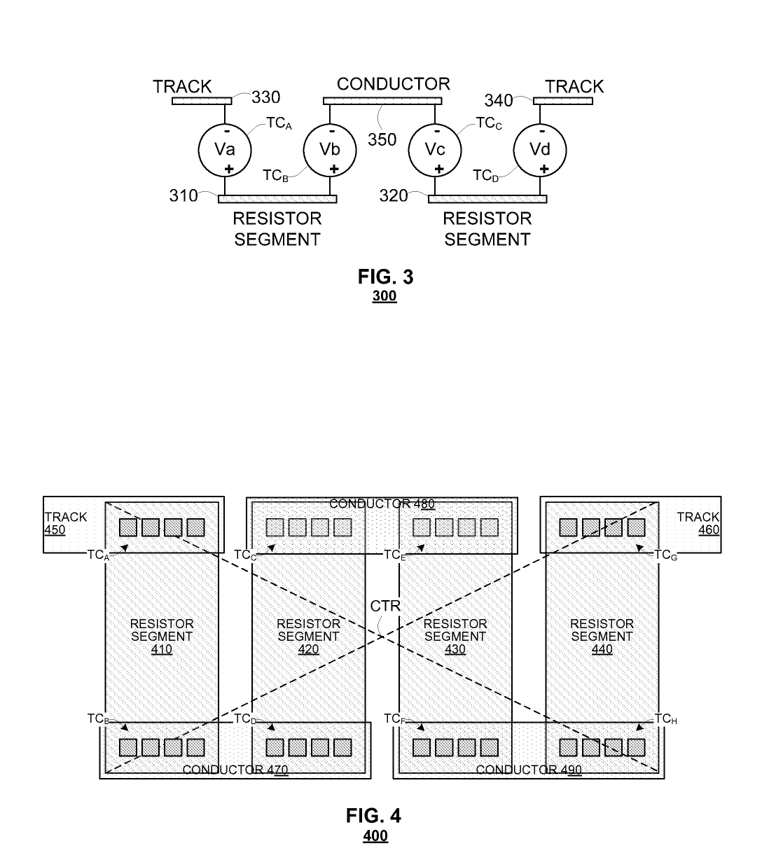

FIG. 2 illustrates a layout of a resistor 200 according to one embodiment of the present invention. The resistor 200 may include two resistor segments 210, 220 and three conductors 230, 240, 250. The first two conductors 230, 240 (shown as “tracks”) may be coupled to respective resistor segments 210, 220 at junctions. The tracks 230, 240 may provide input/output terminals to resistor 200. Each junction between the tracks 230, 240 and the resistor segments 210, 220 forms a junction (i.e., thermocouple), shown generally as TC_{A} for track 230 and TC_{D} for track 240. The third conductor 250 may connect the second ends of the resistor segments 210, 220 to each other. Each junction between the third conductor 250 and the resistor segments 210, 220 forms a junction, shown generally as TC_{B} and TC_{C} respectively, for conductor 250. Each junction generates a voltage, discussed further in FIG. 3.

The resistor segments 210, 220 may be placed in a spatial region of an integrated circuit. As illustrated in FIG. 2, each junction formed between the resistor segments 210, 220 and the conductors 230, 240, 250 may be placed at a location about a centroid of the resistor 200 (shown as CRT). The centroid may be provided as the geometric center of the resistor 200. In an embodiment, the centroid may be defined as the average value of the x-y coordinates of the junctions TC_{A}, TC_{B}, TC_{c}, and TC_{D}. Moreover, each junction may include multiple contacts, for example parallel rectangular contacts, and, hence, each junction may also include a center position. Thus, the centroid may be provided with respect to the center position of each junction.

Each junction may be paired with a similar type (i.e., N-type or P-type) counterpart where the pair form a centroid of that junction type. Junction type may be classified based on current flow direction through the resistor segments. For example, a junction with current flow from a metal portion to resistor may be classified as a first type of junction, and another junction with current flow from resistor to metal portion may be classified as a second type of junction. Further, each junction and its pair counterpart may be spaced from the resistor centroid at a common distance. For instance, junctions TC_{A} and TC_{c} are arranged symmetrically with respect to the resistor centroid and may be classified as the first type of junction, J_{MR} (Junction with metal-to-resistor current flow). Similarly, junctions TC_{B} and TC_{D} are arranged symmetrically with respect to the centroid and may be classified as the second type of junction, J_{RM} (Junction with resistor-to-metal current flow). The paired junctions may have opposite polarities to each other. Consequently, the junction voltages associated with paired junctions TC_{A} and TC_{C} are likely to cancel out junctions voltages associated with paired junctions TC_{B} and TC_{D} in the resistor 200.

Furthermore, the resistor 200 may be used as a resistor connecting to a pad. For example, the conductors 230, 240, 250 may be coupled to a conductive bonding pad.

FIG. 3 is an electrical model of the embodiment of the resistor 300 described in FIG. 2. The model includes two resistor segments 310, 320 and three conductors 330, 340, 350. Junctions TC_{A}, TC_{B}, TC_{C}, and TC_{D} in FIG. 3 are modeled as voltages Vₐ, V_{b}, V_{c}, and V_{d}. The voltages Vₐ-V_{d} represent the total thermoelectric potential at each respective thermocouple. These voltages may vary based on temperature.

The total thermoelectric potential (or offset voltage), Vₜₒₜ, developed between tracks 330 and 340 is:

Vₜₒₜ=Vₐ−V_{b}+V_{c}−V_{d} Eq.(1.)

Therefore, the thermoelectric potential (or offset voltage) of the resistor circuit 300 can be cancelled as long as:

Vₐ+V_{c}=V_{b}+V_{d} Eq. (2.)

In the present embodiment, illustrated in FIG. 3, the junction pairs TC_{A}, TC_{C} and TC_{B}, TC_{D} are arranged symmetrically about a centroid of resistor 300. Therefore, assuming thermal gradients across each resistor segment 310, 320 are linear, the temperature at each of the junctions meets the following equation:

TEMP_{TCa}+TEMP_{TCc}=TEMP_{TCb}+TEMP_{TCd} Eq. (3.)

Where TEMP_{TCa} is the temperature at TC_{A}, TEMP_{TCb} is the temperature at TC_{B}, TEMP_{TCc} is the temperature at TC_{c}, and TEMP_{TCd} is the temperature at TC_{D}.

Because the thermoelectric potential is a linear function of temperature, the overall thermoelectric potential (or offset voltage), Vₜₒₜ, should be:

Vₐ−V_{b}+V_{c}−V_{d}=K* (TEMP_{TCa}+TEMP_{TCc}−TEMP_{TCb}−TEMP_{TCd}) Eq. (4.)

Where K is a constant related to the conductive materials that form the junction. Again, the overall thermoelectric potential (or offset voltage) becomes zero when TEMP_{TCa}+TEMP_{TCc}=TEMP_{TCb}+TEMP_{TCd}.

FIG. 4 illustrates a layout of an offset reducing resistor circuit according to another embodiment of the present invention. In this embodiment, the resistor 400 may include four resistor segments 410, 420, 430, 440 and five conductors 450, 460, 470, 480, 490. The first two conductors 450, 460 (shown as “tracks”) may be coupled to respective resistor segments 410, 440 at junctions. The tracks 450, 460 may provide input/output terminals to the resistor 400. Each junction between tracks 450, 460 and resistor segments 410, 440 forms a junction, shown generally as TC_{A} for track 450 and TC_{G} for track 460.

Intermediate conductors 470, 480, 490 may connect the resistor segments 410, 420, 430, 440. Intermediate conductors 470, 480, 490 and resistor segments 410, 420, 430, 440 may form a conductive pathway from track 450 to track 460. Conductor 470 may connect resistor segments 410 and 420, conductor 480 may connect resistor segments 420 and 430, and conductor 490 may connect resistor segments 430 and 440. Each junction between conductors 470, 480, 490 and resistor segments 410, 420, 430, 440 forms a junction. The junction between conductor 470 and resistor segment 410 is shown as TC_{B}, the junction between conductor 480 and resistor segment 420 is shown as TC_{C}, etc.

Resistor segments 410, 420, 430, 440 may be placed in the spatial region of an integrated circuit. As illustrated in FIG. 4, each junction, TC_{A}-TC_{H}, formed between resistor segments 410, 420, 430, 440 and conductors 450, 460, 470, 480, 490 may be placed at a location about a centroid of resistor 400. Each junction may be paired with a similar type (i.e., N-type or P-type) counterpart where the pair form a centroid of that junction type. Further, each junction and its pair counterpart may be spaced from the resistor centroid at a common distance. For instance, junctions TC_{A} and TC_{H} are arranged symmetrically with respect to the resistor centroid, junctions TC_{B} and TC_{G} are arranged symmetrically with respect to the resistor centroid, etc. The paired junctions may have opposite polarities to each other. Consequently, similar to the embodiment illustrated in FIG. 2., the paired junction voltages in FIG. 4 are likely to cancel each other out in the resistor circuit 400.

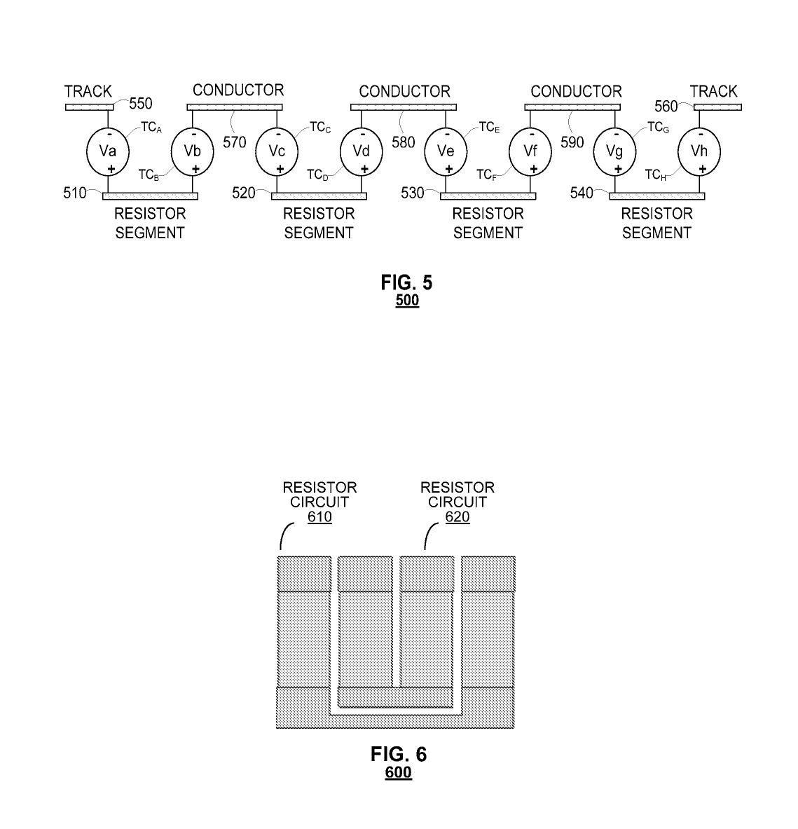

FIG. 5 is an electrical model of the embodiment of the resistor circuit 500 described in FIG. 4. The model illustrates four resistor segments 510, 520, 530, 540 and five conductors 550, 560, 570, 580, 590. Junctions TC_{A}-TC_{H} are modeled as voltages Vₐ-Vₕ. Voltages Vₐ-Vₕ represent the total thermoelectric potential at each respective junction. These voltages may vary based on temperature.

The total thermoelectric potential (or offset voltage), Vₜₒₜ, developed between tracks 550 and 560 is:

Vₜₒₜ=Vₐ−V_{b}+V_{c}−V_{d}+Vₑ−V_{f}+V_{g}−Vₕ Eq. (5.)

As described in the discussion of FIGS. 2 and 3 above, thermal gradients in the embodiment illustrated in FIG. 5 are expected to be similar within resistor segments that are positioned at common locations around the centroid—meaning, effects in resistor segment 520 are likely to be similar to those in resistor segment 530 and effects in resistor segment 510 are likely to be similar to those in resistor segment 540. By extension, thermal effects in each of the junctions TC_{A}-TC_{H} are likely to be similar to those of a counterpart junction (e.g., TC_{A} should be similar to TC_{H}, TC_{B} should be similar to TC_{G}, etc.). Consequently, the voltages among the junctions are likely to cancel out in large measure.

In another embodiment, the resistor may be utilized in integrated circuit systems made up of active and passive devices that generate heat. In such an embodiment it may be beneficial to distribute paired junctions symmetrically about a thermal centroid of the system to achieve offset voltage cancellation. In this case, the centroid of the system may be different than the centroid of the resistor.

In another embodiment, shown in FIG. 6, two resistor circuits 610, 620 according to the pervious embodiments may be arranged similarly and in close proximity to each other on an integrated circuit. In such an embodiment, reducing the voltage offset of each individual resistor circuit according to the principles of the present invention will reduce the overall voltage offset generated between the two resistor circuits. Specifically, because both resistor circuits 610, 620 are arranged in close proximity to each other, corresponding pairs of junctions in each of the resistor circuits 610, 620 will experience similar thermal effects. According to such an embodiment, the voltage difference between the two resistor circuits 610, 620 will be reduced, therefore the voltage offset generated between the two resistor circuits will be reduced. The FIG. 6 embodiment may be particularly applicable for a differential signal where the two resistor circuits 610, 620 may reduce the offset voltage arising between the positive and negative parts of the differential signal.

The resistor segments in the foregoing embodiments are illustrated as generally linear segments, however, the principles of the present invention are not so limited. The principles of the present invention may accommodate any other geometric shapes—such as circular arcs or elbows—as long as there are an even number of metal-silicon junctions arranged symmetrically about a common centroid and connected in series. Arranging the metal-silicon junctions in such a manner minimizes the voltages generated by the metal-silicon junctions due to the Seebeck effect.

Although the foregoing discussion suggests perfect cancellation of voltages will occur, these represent idealized cases. Perfect cancellation is unlikely to occur when the resistors are manufactured in integrated circuits. When resistors are fabricated, they are unlikely to behave exactly as described in the circuit models illustrated in FIGS. 3 and 5. For example, thermal gradients are unlikely to be perfectly linear and small device mismatches may occur. Nevertheless, the arrangements illustrated in FIGS. 2-6 can greatly reduce the overall offset voltages generated by such resistors.

Several embodiments of the invention are specifically illustrated and/or described herein. However, it will be appreciated that modifications and variations of the invention are covered by the above teachings and within the purview of the appended claims without departing from the spirit and intended scope of the invention.

We claim:

1. A resistor circuit, comprising:
a first and second resistor segment, each segment having a first end and a second end,
a first conductor coupled to the first end of the first segment forming a first junction;
a second conductor coupled to the first end of the second segment forming a second junction; and
a third conductor coupled to the second ends of both resistor segments forming a third junction with respect to the first resistor segment and a fourth junction with respect to the second resistor segment;
wherein junctions of a first type form a first centroid that is substantially coincident to a second centroid formed by junctions of a second type.

2. The resistor circuit of claim 1, wherein the first type of junctions include the first and fourth junctions, and the second type of junctions include the second and third junctions.

3. The resistor circuit of claim 1, wherein the first type of junctions include junctions with current flow from metal to resistor and the second type of junctions include junctions with current flow from resistor to metal.

4. The resistor circuit of claim 1, wherein each junction includes multiple parallel contacts.

5. The resistor circuit of claim 1, wherein at least one conductor is coupled to a conductive bonding pad.

6. The resistor circuit of claim 1, wherein the resistor segments are made of semiconductor material.

7. The resistor circuit of claim 1, wherein the resistor segments are poly silicon resistors.

8. The resistor circuit of claim 1, wherein the resistor segments are N-type diffusion resistors.

9. The resistor circuit of claim 1, wherein the resistor segments are P-type diffusion resistors.

10. The resistor circuit of claim 1, wherein the resistor segments are N-type well resistors.

11. The resistor circuit of claim 1, wherein the resistor segments are P-type well resistors.

12. The resistor circuit of claim 1, wherein the resistor segments have a linear shape.

13. The resistor circuit of claim 1, wherein the resistor segments have an arc-like shape.

14. The resistor circuit of claim 1, wherein the resistor segments have an elbow shape.

15. The resistor circuit of claim 1, wherein the conductors are made of metal.

16. The resistor circuit of claim 1, wherein the resistor segments are disposed in an integrated circuit.

17. A resistor circuit, comprising:
a first and second resistor segment,
a first and second conductor coupled to the respective resistor segments at junctions, and
a third conductor coupled to the other ends of the resistor segments at junctions,
wherein corresponding pairs of junctions of differing types are located at symmetrical positions to form respective junction type centroids that are substantially coincident with each other.

18. The resistor circuit of claim 17, wherein the junction types are classified based on current flow direction.

19. The resistor circuit of claim 17, wherein the resistor segments are made of semiconductor material.

20. The resistor circuit of claim 17, wherein the resistor segments are poly silicon resistors.

21. The resistor circuit of claim 17, wherein the resistor segments are N-type diffusion resistors.

22. The resistor circuit of claim 17, wherein the resistor segments are P-type diffusion resistors.

23. The resistor circuit of claim 17, wherein the resistor segments are N-type well resistors.

24. The resistor circuit of claim 17, wherein the resistor segments are P-type well resistors.

25. The resistor circuit of claim 17, wherein the resistor segments have a linear shape.

26. The resistor circuit of claim 17, wherein the resistor segments have an arc-like shape.

27. The resistor circuit of claim 17, wherein the resistor segments have an elbow shape.

28. The resistor circuit of claim 17, wherein the conductors are made of metal.

29. A resistor circuit comprising:
a plurality of resistor segments disposed in an integrated circuit coupled to conductors at a plurality of junctions,
wherein pairs of junctions are distributed throughout the integrated circuit at locations forming respective junction centroid of each type, wherein the centroids are substantially coincident.

30. The resistor circuit of claim 29, wherein at least two pairs of junctions are different junction types based on current orientation.

31. The resistor circuit of claim 29, wherein the resistor segments are made of semiconductor material.

32. The resistor circuit of claim 29, wherein the resistor segments are poly silicon resistors.

33. The resistor circuit of claim 29, wherein the resistor segments are N-type diffusion resistors.

34. The resistor circuit of claim 29, wherein the resistor segments are P-type diffusion resistors.

35. The resistor circuit of claim 29, wherein the resistor segments are N-type well resistors.

36. The resistor circuit of claim 29, wherein the resistor segments are P-type well resistors.

37. The resistor circuit of claim 29, wherein the resistor segments have a linear shape.

38. The resistor circuit of claim 29, wherein the resistor segments have an arc-like shape.

39. The resistor circuit of claim 29, wherein the resistor segments have an elbow shape.

40. The resistor circuit of claim 29, wherein the conductors are made of metal.

41. The resistor circuit of claim 29, wherein the pairs of junctions are located at symmetrical positions with respect to a centroid of the resistor segments.

42. The resistor circuit of claim 29, wherein the pairs of junctions are located at symmetrical positions with respect to a thermal centroid of the integrated circuit.

43. An apparatus for an integrated circuit, comprising:
a plurality of semiconductor segments interconnected via metal conductors, connections between individual segments and conductors forming a respective junction,
wherein junctions of a first type form a first type centroid that is substantially coincident to a second type centroid formed by junctions of a second type.

44. The apparatus of claim 43, wherein the segments are poly silicon resistors.

45. The apparatus of claim 43, wherein the segments are N-type diffusion resistors.

46. The apparatus of claim 43, wherein the segments are P-type diffusion resistors.

47. The apparatus of claim 43, wherein the segments are N-type well resistors.

48. The apparatus of claim 43, wherein the segments are P-type well resistors.

49. The apparatus of claim 43, wherein the segments have a linear shape.

50. The apparatus of claim 43, wherein the segments have an arc-like shape.

51. The apparatus of claim 43, wherein the segments have an elbow shape.

52. An apparatus for an integrated circuit, comprising:
two resistor circuits arranged similarly and located in close proximity to each other on the integrated circuit,
a first resistor circuit comprising:
a plurality of semiconductor segments interconnected via metal conductors, connections between individual segments and conductors forming a respective junction,
wherein junctions of a first type form a first type centroid that is substantially coincident to a second type centroid formed by junctions of a second type,
a second resistor circuit comprising:
a plurality of semiconductor segments interconnected via metal conductors, connections between individual segments and conductors forming a respective junction,
wherein junctions of a first type form a first type centroid that is substantially coincident to a second type centroid formed by junctions of a second type.

53. The apparatus of claim 52, wherein the segments are poly silicon resistors.

54. The apparatus of claim 52, wherein the segments are N-type diffusion resistors.

55. The apparatus of claim 52, wherein the segments are P-type diffusion resistors.

56. The apparatus of claim 52, wherein the segments are N-type well resistors.

57. The apparatus of claim 52, wherein the segments are P-type well resistors.

58. The apparatus of claim 52, wherein the segments have a linear shape.

59. The apparatus of claim 52, wherein the segments have an arc-like shape.

60. The apparatus of claim 52, wherein the segments have an elbow shape.

61. The apparatus of claim 52, wherein the apparatus is configured to receive a differential signal.
